(19) United States
(12) Patent Application Publication
(10) Pub. No.: US 2002/0184578 A1
(43) Pub. Date: Dec. 5, 2002

(54) Semiconductor integrated circuit

(76) Inventor: Yutaka Yoshizawa, Tokyo (JP)

Correspondence Address: Darryl G. Walker, WALKER & SAKO, LLP, Suite 235, 300 South First Street, San Jose, CA, 95113, US

(21) Appl. No.: 10/156,567

(22) Filed: May 28, 2002

(30) Foreign Application Priority Data
May 31, 2001 (JP) 2001-164830

(51) Int. Cl. G11C 29/00

(52) U.S. Cl. 714/718

(57) ABSTRACT

A built in self test (BIST) circuit (100) including an address generator (3) providing an address including a subarray address is disclosed. Address generator (3) may include an address counter (4), a address modulation circuit (5), a subarray under test designating circuit (6), and an address scramble circuit (7). Address modulation circuit (5) may modulate an address counter output (4a) in accordance with a test mode (19). Subarray under test designating circuit (6) may provide an address for a subarray to be tested. A memory interface block (9) may receive the address (17 and 18) from address generator (3) and test mode (19) and may generate a memory test command accordingly. Address (17 and 18) and test mode (19) may be provided external to BIST circuit (100). In this way, a memory may be tested using complicated patterns and failure modes and location may be identified.

### TECHNICAL FIELD

The present invention relates generally to a semiconductor integrated circuit and more particularly to a built-in self test circuit which may be capable of implementing tests using address patterns which may be complex.

### BACKGROUND OF THE INVENTION

Semiconductor integrated circuits including random access memories (RAMs) can have memory bits within the RAM tested to verify functionality. One method of testing the RAM is to have a built-in self test (BIST) circuit.

FIG. 22 is a block schematic diagram of a conventional BIST circuit given the general reference character 2200.

Conventional BIST circuit 2200 has an address generator 102, a test mode control and data generator (test mode controller) 101, a RAM interface block 105, and a comparator 106.

Test mode controller 101 controls the test mode and generates test data. Test mode controller 101 receives a clock CLK, a reset signal RST, and a test mode switching signal 103c and outputs a test mode signal 101b, a data signal 101c, an ascending/descending order designating signal 101a, and a count trigger signal 101d.

Address generator 102 receives clock CLK, reset signal RST, and ascending/descending order designating signal 101a, and count trigger signal 101d and outputs an X address (Row address) 104a and a Y address (Column address) 104b.

RAM interface block 105 receives X address 104b, Y address 104a, test mode signal 101b, and data signal 101c, clock CLK, and reset signal RST. Utilizing these inputs, RAM interface block 105 outputs a RAM input command address 111. RAM input command address 111 matches an interface specification of the RAM under test.

Comparator 106 compares a testing RAM output data 110 with an expected value data (data signal) 101c and outputs a comparison result 109.

Address generator 102 includes an address counter 103 and an address scrambler 104.

Address counter 103 receives reset signal RST, count trigger signal 101d, and ascending/descending order designating signal 110a and outputs a Y address count 103a and X address count 103b.

Address scrambler 104 receive Y address count 103a and X address count 103b and outputs a Y address 104a and a X address 104b.

The operation of conventional BIST circuit 2200 will now be described.

After a reset operation, reset signal RST resets the test mode signal 101b to a “1”. The RAM can be reset during the reset operation, depending on a RAM type, such as a synchronous dynamic random access memory (SDRAM).

Hereafter, every time test mode switching signal 103c is applied to test mode controller 101, test mode signal 101b is incremented, so as to be 2, 3, 4, . . ., for example.

In conventional BIST circuit 2200, one type of test mode is matched to each value of test mode signal 101b.

For each test mode, test mode controller 101 defines whether address counts (103a, 103) are incremented or decremented and whether to perform data writing or data reading. When writing data, test mode controller 101 defines whether write data is a “1” or “0”. When reading data, test mode controller 101 defines whether an expected data value is “1” or “0”. Test mode controller 101 also defines the count-up timing of address counter 103 and controls each circuit in conventional BIST circuit 2200.

During a write operation, data signal 101c is write data. During a read operation, data signal 101c is an expected data value and compared with RAM output data 110.

Test mode controller 101 outputs ascending/descending order designating signal 101a. Ascending/descending order designating signal 101a indicates whether address counter 103 increments or decrements address counts (103a and 103b).

Test mode controller outputs a count trigger signal 101d. Count trigger signal 101d is a timing signal setting a timing for a count (increment) of address counter 103.

After a reset operation and reset signal 108 is returned to a normal state, address counter 103 receives count trigger signal 101d and begins counting.

Address counter 103 counts in the same manner regardless as to the logic level of ascending/descending order designating signal 101a provided from test mode controller 101. If ascending/descending order designating signal 101a indicates ascending order, the output of address counter 103 is provided directly as address counts (103a and 103b). In contrast, if ascending/descending order designating signal 101a indicates descending order, an inverted output of address counter 103 is provided as address counts (103a and 103b).

In order to minimize physical layout of the RAM, the physical addresses in the RAM may not be in a simple binary sequence. Thus, an address scrambler 104 is provided to change Y address count 103a and X address count 103b to provide Y address 104a and X address 104b into a physical address order of the RAM under test.

Conventional BIST circuit 2200 can have the following drawbacks.

(1) Tests other than checkerboard and marching tests cannot be implemented. Thus, the ability to detect sources of function defects in the RAM under test may be limited.

(2) Testing time may not be reduced. For example, after writing data into an address location and then accessing all other address locations in a test to read out the data, testing time can be greatly shortened if only testing the one subarray at a time to detect defects. However, testing time could not be reduced with conventional BIST circuits.

(3) Faults could be detected on the RAM under test, but determining the fault location and defect mode is difficult or impossible.

Therefore, even if conventional BIST circuit 2200 is used to test a RAM, some defect modes are difficult or impossible to detect. Thus, it is possible that a large scale integrated (LSI) device is shipped with a RAM macro or a RAM having defects. Conventional BIST circuit 2200 is also incapable of performing sufficient fault analysis.

A BIST circuit capable of performing tests other than checkerboard and marching tests is needed. A BIST circuit capable of detecting defect mechanisms in the RAM under test is needed. A BIST circuit capable of shortening test time is needed. A BIST circuit capable of providing or estimating a fault location and a defect mode of the RAM under test is needed.

A semiconductor integrated circuit device having a memory self-test function is disclosed in Japanese Patent Laid-open No. 2000-163992 (JPA '992). In JPA '992, the semiconductor integrated circuit device is provided with an address generator for generating a self-test address in accordance with an external clock and an address reset circuit for resetting the self-test address generated by the address generator. The address reset circuit resets the self-test address generated by the address generator according to a memory capacity discriminating signal corresponding to a memory capacity of a memory section. The semiconductor integrated circuit device also includes a data generator, a memory control signal generator, a memory section, and a comparator circuit. The data generator receives an output signal from the address generator and generates self-test data. The memory control signal generator receives the outputs signal of the address generator and generates a memory control signal. The comparator circuit decides a pass or fail based on the output signal of the address generator and the self-test data read out from the memory and outputs the pass/fail signal.

A semiconductor integrated circuit device having a test circuit is disclosed in Japanese Patent Application Laid-open No. 2000-163993 (JPA '993). The test circuit of JPA '993 includes a single self-test circuit section and a plurality of memory circuit sections formed on the same chip. The self-test circuit section includes a single address and access signal generating means for generating access signals and a maximum address for the plurality of memory sections for testing the plurality of memory circuit sections. The self-test circuit section also includes a single data generating means for generating test data with a maximum data bit width in the plurality of memory circuit sections for testing the plurality of memory circuit sections and a single memory circuit section largest address storage means for storing the largest address value of each of the plurality of memory circuit sections. The self-test circuit section further includes a single address deciding means to determine, for each of the multiple memory circuit sections, that the address generated by the address and access signal generating means are equal to or greater than the address set by the memory circuit section largest address storage means and to generate refresh operation signals in a number equal to the number of multiple memory circuit sections. The self-test circuit section also includes address and access signal control means in a number equal to the number of multiple memory circuit sections. The address and access signal control means disables access and addresses generated by the address and access signal generation means by using the multiple refresh operation signals generated by the address decision means. The self-test circuit section also includes refresh generation means in a number equal to the number of multiple memory circuit sections. The refresh generation means generates refresh signals using the multiple refresh operation signals generated by the address decision means. The self-test circuit section also includes a data comparison signal control means in a number equal to the number of multiple memory circuit sections. The data comparison signal control means disables read-out data comparison signals of the multiple memory circuit sections using the multiple refresh operation signals generated by the address decision means. The self-test circuit section also includes a comparison means in a number equal to the number of multiple memory circuit sections. The comparison means compares each data value read out from the multiple memory circuit sections with data values generated by the data generation means by using the read out data comparison signals propagated from the multiple data comparison signal control means. The self-test circuit section also includes a signal BIST control means for controlling the data generation means and address and access signal generation means according to a test algorithm, testing the multiple memory circuit sections, and outputting the presence or absence of errors in the multiple memory circuit sections in accordance with comparison results returned from the multiple comparison means.

Another BIST circuit for a semiconductor device is disclosed in Japanese Patent Application Laid-Open No. 2000-076894 (JPA '894). In JPA '894, the BIST circuit performs tests utilizing multiple test patterns for a storage section provided in the semiconductor device. The BIST circuit includes an address counter, a control signal output circuit, a processed data output circuit, and a test pattern generation circuit. The address counter outputs an end signal each time a series of write/read processing of a predetermined number of addresses in the storage section is completed. The control signal output circuit sequentially outputs common control signals each time the end signal is received. The processed data output circuit has multiple encoded processed data and sequentially decodes and outputs the processed data according to each of the received common control signals. The test pattern generation circuit outputs bit data corresponding to the processed data received from the processed data output circuit as each test pattern to the storage section.

A BIST macro of a processor base is disclosed in Japanese Patent Application Laid-Open No. Hei 10-241399 (JPA '399). In JPA '399, the BIST macro of a processor base performs tests of a dynamic random access memory built in a logic chip. The BIST macro contains a means for storing test commands and a processor means. The processor means reads out the test commands, generates test patterns from the test commands, and gives the test commands a sequence.

A self-test circuit of a composite semiconductor memory device is disclosed in Japanese Patent Application Laid-Open No. Hei 11-317096 (JPA '096). In JPA '096, a composite semiconductor memory device including logic and a memory composed of multiple banks configured on a single chip. The self-test circuit includes a BIST information generation means and a switching means. The BIST information generation means generates predetermined BIST information signals in response to external clock signals and BIST mode designating signals. In a normal mode, the switching means utilizes a logic clock signal output from the logic and a logic information signal as input signals for providing the generated output signals to the memory. In a BIST mode, the switching means utilizes the external clock signal and the BIST information signal as input signals for providing the generated output signal to the memory. In the BIST mode, the BIST information generation means compares data written in the memory with data output from the memory and detects addresses of banks where faults are occurring.

In view of the above discussion, it would be desirable to provide semiconductor integrated circuit addressing the above-mentioned problems. It would also be desirable to provide semiconductor integrated circuit that may be capable of implementing tests other than a checkerboard and marching tests. It would also be desirable to provide a semiconductor integrated circuit that may be capable of detecting a cause of a functional defect in a RAM (random access memory) under test. It would also be desirable to provide a semiconductor integrated circuit that may be capable of reducing the test time. It would also be desirable to provide a semiconductor integrated circuit that may be capable of determining a fault location or vicinity. It would also be desirable to provide a semiconductor integrated circuit that may be capable of detecting a defect mode of the RAM under test.

### SUMMARY OF THE INVENTION

According to the present embodiments, a built in self test circuit (BIST) may include an address generator. An address generator may provide an address including a subarray address. An address generator may include an address counter, an address modulation circuit, a subarray under test designating circuit, and an address scramble circuit. Address modulation circuit may modulate an address counter output in accordance with a test mode. Subarray under test designating circuit may provide an address for a subarray to be tested. A memory interface block may receive the address from address generator and a test mode and may generate a memory test command accordingly. An address and a test mode may be provided external to the BIST circuit. In this way, a memory may be tested using complicated patterns and failure modes and location may be identified.

According to one aspect of the embodiments, an integrated circuit for testing a random access memory (RAM) may include an address counter, an address modulator circuit and a RAM interface block. The address counter may count an address of the RAM and provide an address count. The address modulator circuit may be coupled to receive the address count and may modulate the address count in accordance with a test mode to provide a modulation address. A RAM interface block may be coupled to provide a test command to the RAM on the basis of the modulated address and the test mode.

According to another aspect of the embodiments, the address counter may increment the address of the RAM.

According to another aspect of the embodiments, the address counter may decrement the address of the RAM.

According to another aspect of the embodiments, a memory cell array of the RAM may be divided in to a plurality of subarrays. The semiconductor integrated circuit may further include a designating circuit. The designating circuit may be coupled to receive the modulation address and provide a designated subarray address. The RAM interface block may provide the test command on the basis of the designated subarray address and the test mode.

According to another aspect of the embodiments, the semiconductor integrated circuit may further include a count final value detector circuit. The count final value detector circuit may reset the address counter and may terminate the test in progress when the address count reaches a predetermined count final value.

According to another aspect of the embodiments, the address counter may be reset to terminate the test in progress in response to an address counter reset signal provided from outside the semiconductor integrated circuit.

According to another aspect of the embodiments, the test mode and an address received by the RAM are provided as semiconductor integrated circuit outputs.

According to another aspect of the embodiments, a semiconductor integrated circuit may include a memory and a built in self test (BIST) circuit. The BIST circuit may include an address counter, an address modulator circuit, and a memory interface block. The address counter may provide an address count. The address modulator circuit may be coupled to receive at least a first portion of the address count and provide an address modulator output in accordance with a test mode and the at least a first portion of the address count. The memory interface block may be coupled to receive the address modulator output and provide a test command to the memory.

According to another aspect of the embodiments, the memory may be a dynamic random access memory (DRAM).

According to another aspect of the embodiments, the BIST circuit may provide a disturb-hold test.

According to another aspect of the embodiments, the memory may include a plurality of subarrays. The BIST circuit may include a subarray under test designating circuit. The subarray under test designating circuit may receive the test mode and select a subarray to be tested.

According to another aspect of the embodiments, the address modulator circuit may include a selector that designates the address modulator output to be even in response to a first test mode and designates the address modulator output to be odd in response to a second test mode.

According to another aspect of the embodiments, the address counter may receive an increment/decrement signal. The increment/decrement signal may have an increment logic level and a decrement logic level. The address counter may provide the address count in an incrementing sequence when the increment/decrement signal has the increment logic level and may provide the address count in a decrementing sequence when the increment/decrement signal has the decrement logic level.

According to another aspect of the embodiments, the BIST circuit may include a selector circuit coupled to provide at least a second portion of the address count to the memory interface block in a first test mode and the address modulator output to the memory interface block in a second test mode.

According to another aspect of the embodiments, a semiconductor integrated circuit may include a memory divided into a plurality of subarrays and a built in self test (BIST) circuit for the memory. The BIST circuit may include an address generator and a memory interface block. The address generator may provide a test address based on a counter output and a subarray address. The memory interface block may be coupled to receive the test address and a test mode and provide a test command to the memory.

According to another aspect of the embodiments, the test command may include a memory test address and at least one memory control signal.

According to another aspect of the embodiments, the test mode and the test address may be provided to circuits external to the BIST circuit.

According to another aspect of the embodiments, the BIST circuit may provide at least one test from the group consisting of a marching test, a checkerboard test and a disturb-hold test.

According to another aspect of the embodiments, the memory may be a dynamic random access memory.

According to another aspect of the embodiments, the address generator may include a final value detection circuit. The final value detection circuit may provide a count stop signal to a counter providing the counter output.

### BRIEF DESCRIPTION OF THE DRAWINGS

FIG. 1 is a block schematic diagram of a BIST circuit according to an embodiment.

FIG. 2 is a timing diagram illustrating various signals of a BIST circuit according to an embodiment.

FIG. 3 is a block schematic diagram of an address modulator circuit and subarray under test designating circuit of a BIST circuit according to an embodiment.

FIG. 4 is a block schematic diagram of an address counter of a BIST circuit according to an embodiment.

FIG. 5 is a block schematic diagram of a count final value detector of a BIST circuit according to an embodiment.

FIG. 6 is a diagram illustrating a disturb-hold test pattern.

FIG. 7 is a plan diagram illustrating subarrays arranged in a matrix.

FIG. 8 is a table illustrating an example of a test mode performing a checkerboard test according to an embodiment.

FIG. 9 is a table illustrating an example of a test mode performing a marching test according to an embodiment.

FIG. 10 is table illustrating an example of a test mode performing a disturb-hold test according to an embodiment.

FIG. 11 is table illustrating a categorization of address count signals according to an embodiment.

FIG. 12 is a table illustrating test modes for implementing a checkerboard test and a marching test according to an embodiment.

FIGS. 13 and 14 are tables illustrating test modes for implementing a checkerboard test and a marching test according to an embodiment.

FIG. 15 is a table showing the relation between tests implemented in an embodiment and defect modes in a DRAM that can be detected.

FIG. 16 is a table illustrating a probable defect mode based on pass/fail results of each of the collective tests (marching, checkerboard, and disturb-hold).

FIG. 17 is a block schematic diagram of an address counter, an address modulation circuit, and a subarray under test designating circuit according to an embodiment.

FIG. 18 is a block schematic diagram of a count final value detector circuit according to an embodiment.

FIG. 19 is a chart illustrating a fast galloping pattern according to an embodiment.

FIGS. 20 and 21 are tables illustrating sample states/values of signals with a BIST circuit including circuits of FIG. 17 and 18 according to an embodiment.

FIG. 22 is a block schematic diagram of a conventional BIST circuit.

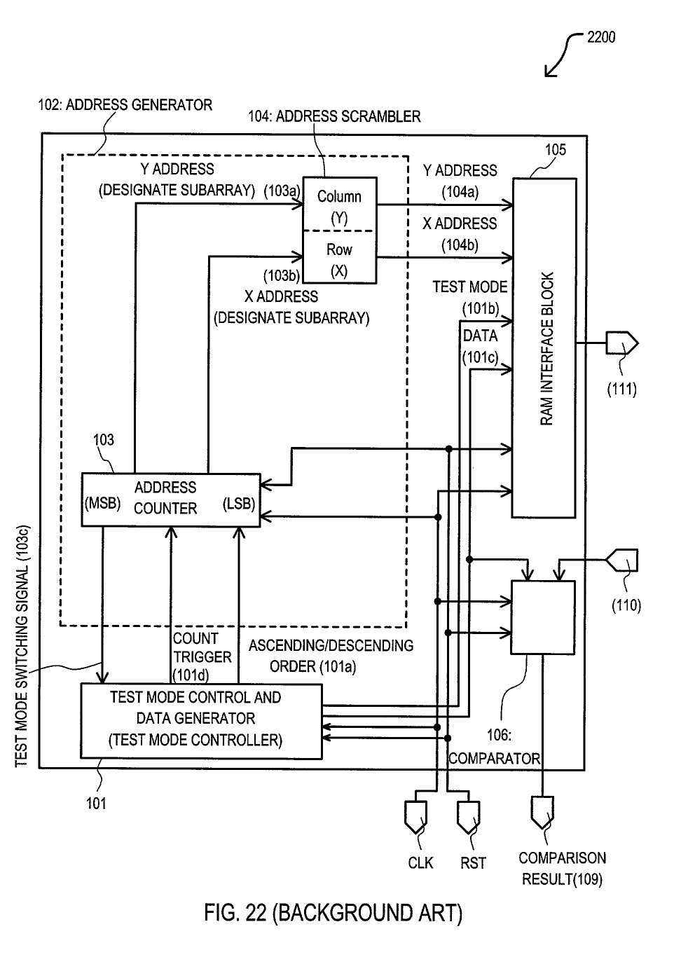

### DETAILED DESCRIPTION OF THE EMBODIMENTS

Various embodiments of the present invention will now be described in detail with reference to a number of drawings.

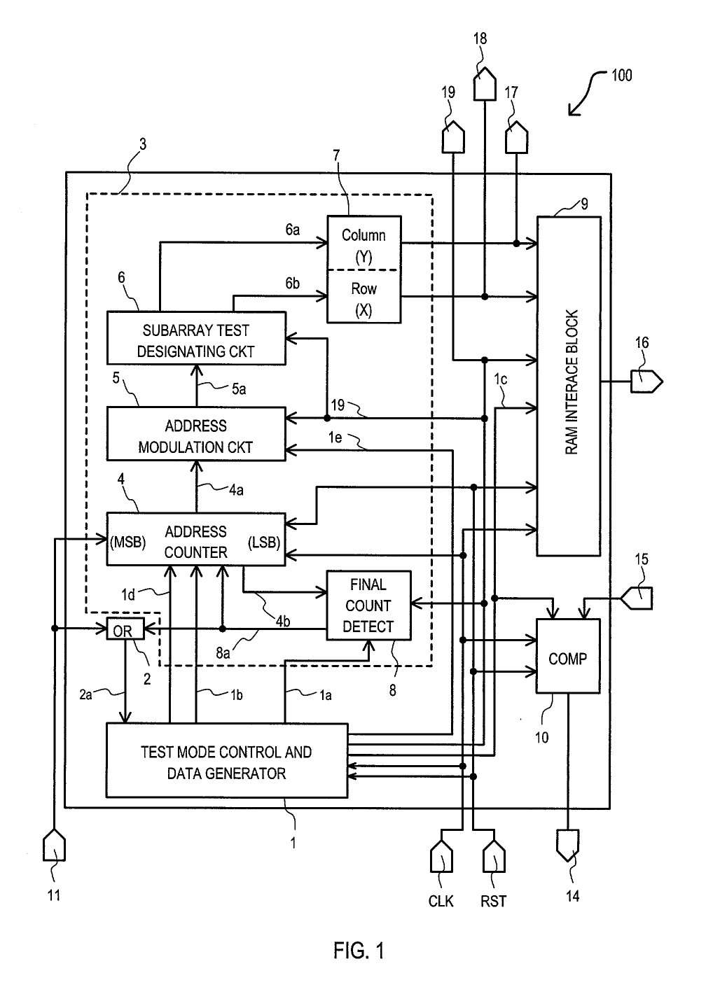

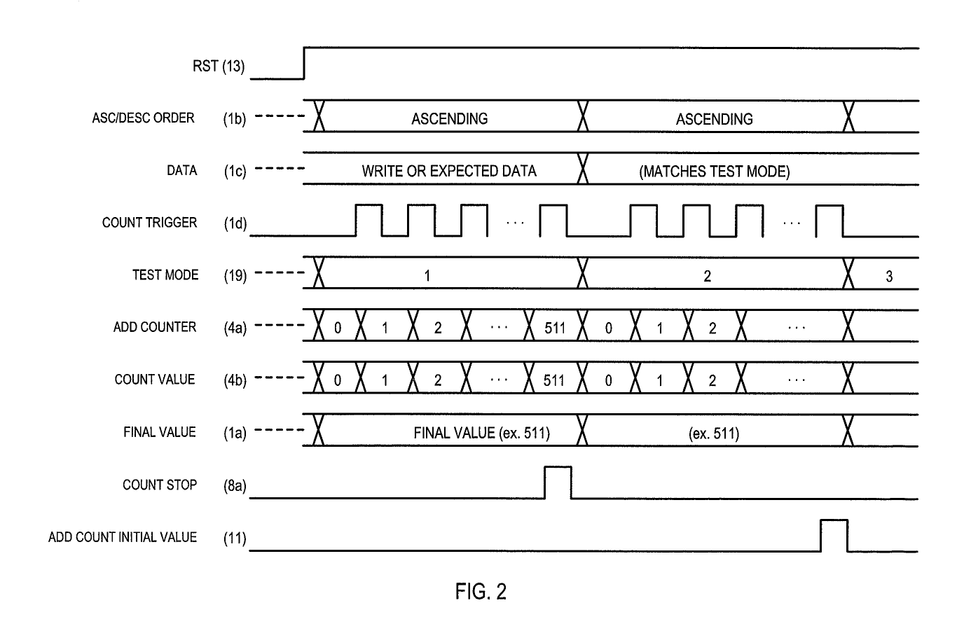

A built-in self test (BIST) circuit of a first embodiment will be described with reference to FIG. 1 and FIG. 2.

Referring now to FIG. 1, a block schematic diagram of a BIST circuit according to an embodiment is set forth and given the general reference character 100.

BIST circuit 100 may include an address generator 3, a test mode control & data generator (test mode controller) 1, an OR gate 2, a random access memory (RAM) interface block 9, and a comparator 10.

Test mode controller 1 may provide control for a test mode and may generate test data. Test mode controller 1 may receive a clock CLK, a reset signal RST, and a test mode switching signal 2a and may output a test mode signal 19, a data signal 1c, an ascending/descending order designating signal 1b, a final value 1a, and a count trigger 1d.

OR gate 2 may generate test mode switching signal 2a obtained by a logical sum of a count stop signal 8a and an address counter reset signal 11. Count stop signal 8a may be provided from address generator 3.

Address generator 3 may receive clock CLK, reset signal RST, address counter reset signal 11, test mode signal 19, ascending/descending order designating signal 1b, an address final value designating signal (final value) 1a, a count trigger signal 1d, and a modulation control signal 1e. Address generator 3 may output an X address (row address) 18, a Y address (column address) 17, and count stop signal 8a.

RAM interface block 9 may receive row address 18, column address 17, test mode signal 19, data signal 1c, clock CLK, and reset signal RST. RAM interface block 9 may output a RAM input command address input data 16. RAM input command address input data 16 may match the interface specifications of the RAM under test. RAM input command address input data 16 may include address signals and command signals for operating the RAM under test.

Comparator 10 may compare RAM under test output data 15 with data signal 1c and may output a comparison result 14. In a read operation, data signal 1c may include expected data. In a write operation, data signal 1c may include write data.

Address generator 3 may include an address counter 4, an address modulation circuit 5, a subarray under test designating circuit 6, an address scrambler 7, and a count final value detection circuit 8.

Address counter 4 may receive reset signal RST, address counter reset signal 11, count trigger signal 1d, ascending/descending order designating signal 1b, and count stop signal 8a. Address counter may output an address count 4a and a count value 4b.

Count final value detection circuit 8 may receive final value 1a and count value 4b. Count final value detection circuit 8 may output count stop signal 8a.

Address modulator 5 may receive address count 4a, test mode signal 19, and a modulation control 1e. Address modulator 5 may output an address after modulation 5a.

Subarray under test designating circuit 6 may receive address after modulation 5a and test mode signal 19. Subarray under test designating circuit 6 may output a Y address 6a and a X address 6b. Y address 6a and X address 6b may designate a subarray.

Address scrambler 7 may receive Y address 6a and X address 6b. Address scrambler 7 may output row address 18 and column address 17.

Test mode signal 19, row address 18, and column address 17 may be provided to circuitry (not shown) outside the BIST circuit 100.

The operation of BIST circuit 100 will now be described. FIG. 2 is a timing diagram illustrating various signals of BIST circuit 100 in an operation.

After a reset operation and reset signal RST returns to a non-reset state (in this case logic high), test mode signal 19 may be set to a 1. In certain RAM types, such as a synchronous dynamic random access memory (SDRAM), the RAM may be required to be initialized.

Test mode signal 19 may be incremented (2, 3, 4, . . ., etc) hereafter, every time test mode switching signal 2a is provided to test mode controller 1. Test mode switching signal 2a may be provided to test mode controller 1 when either count stop signal 8a or address counter reset signal 11 becomes a high logic level. In this case OR gate 2 may apply test mode switching signal 2a having a high logic level to test mode controller 1.

BIST circuit 100 may have one type of test mode designated for each acquired value of test mode signal 19.

For each test, test mode controller 1 may define whether address signal 4a is ascending or descending order, and whether to perform data writing or data reading. When writing data, test mode controller 1 may define whether write data is a “1” or a “0”. When reading data, test mode controller 1 may define whether a value of expected data is a “1” or a “0”. Test mode controller 1 may also define a count-up timing (count trigger 1d) of address counter 4 and a count final value 19 of address counter 4, and may control circuits in BIST circuit 100.

Data signal 1c may have a write or expected data value in accordance with the test mode output from test mode controller 1.

Ascending/descending order designating signal 1b may have a value indicating ascending or descending order of the address in accordance with the test mode output from test mode controller 1.

Count trigger signal 1d may provide a timing from test mode controller 1 for address counter 4 to provide count outputs (4a and 4b).

Final value 1a may be a count final value for address counter 4 providing a count outputs (4a and 4b) that may be used in a corresponding test mode as determined by test mode controller 1.

After completing a reset RST, address counter 4 may receive count trigger signal 1d and may count up.

A counter value in address counter 4 may be reset to zero when count stop signal 8a or address counter reset signal 11 are provided. In this case, the counter value may be reset when count stop signal 8a or address counter reset signal 11 are at a high logic level.

Address counter 4 may continually output count value 4b to count final value detector 8.

Address counter 4 may count as described above regardless of the logic level of ascending/descending order designating signal 1b. If ascending/descending order designating signal 1b is at a logic level indicating ascending order, the count value may be output as address count 4a. However, if ascending/descending order designating signal 1b is at a logic level indicating descending order, an inverted count value may be output as address count 4a.

Count final value detector 8 may compare the final value 1a and the count value 4b and may generate count stop signal 8a if count value 4b and filial value 1a are matching.

Address count 4a may be an address value which may be counted in an ascending or descending order. However, address modulator 5 may modulate the received address value to provide an address after modulation 5a. The address after modulation 5a may be an address pattern provided in accordance with a value of test mode signal 19 providing a test mode for a memory, such as a RAM, for example.

When the RAM under test has a large storage capacity (or bit density), cell arrays of the RAM under test may often be divided into a plurality of arrays also known as subarrays. It may be desirable for tests to be performed on each subarray depending on the type of test being performed. Subarray under test designating circuit 6 may output a Y address 6a and X address 6a that may identify a subarray. In this way, a designated subarray may be accessed in the test mode in accordance with test mode signal 19.

In order to reduce the surface area of the chip occupied by the RAM, the memory cells of the RAM may not be arranged in a pure binary address sequence.

Thus, address scrambler 7 may be provided to translate Y address 6a and X address 6b into an address order that may correspond to the physical address order of the RAM under test.

Address scrambler circuit 7 may receive the Y address 6a and X address 6b and may output column address 17 and row address 18. In this way, Y address 6a and X address 6b may be translated to column address 17 and row address 18 which may be a physical address for the RAM under test.

In BIST circuit 100, test mode signal 19, row address 18, and column address 17 may be provided to circuitry external to BIST circuit 100. Test mode signal 19, row address 18, and column address 17 may be provided in real-time in the test mode. In this way, the test mode which is being executed by BIST circuit 100 and an address location being accessed in the RAM under test may be indicated. This may allow BIST circuit 100 to not only perform fault detection of a RAM under test, but also determine or estimate a fault location and/or a defect mode.

The present embodiment may provide the following effects.

(1) BIST circuit 100 may perform tests using complex address patterns required in functional tests of high density RAMs, such as DRAMs or the like, instead of being limited to checkerboard and marching tests that are generally executed with conventional BIST circuits for static random access memories (SRAMs).

Therefore, faults in a RAM under test that may not be detectable using checkerboard and marching tests implemented in a conventional BIST circuit may be detected with other tests which may have more complex address patterns using BIST circuit 100.

(2) Subarrays may be specifically selected and tested.

Thus, BIST circuit 100 may select and access only addresses needed for performing one test. In this way, testing time may be greatly reduced because only selected subarrays may be tested as needed when executing tests to access and read out other addresses after writing data in an optional address.

(3) The fault location and a defect mode may be estimated or determined instead of just detecting that a RAM under test has a fault.

In this way, LSIs, such as a system on a chip or the like, incorporating high density RAM or RAM macros may be tested and shipped in a shorter time as compared to a time for testing a RAM using conventional BIST circuits. Using BIST circuit 100 fault analysis may be performed on a RAM under test, or the like, that has failed tests.

The reasons the above-mentioned effects may be obtained by using BIST circuit 100 are as follows.

(1) An address modulator circuit 5 may be provided inside address generator 3. Address modulator circuit 5 may be capable of modulating the simply incremented or decremented address count 4a output from address counter 4. In this way, an address after modulation 5a may be provided which may be changed as required for the RAM under test according to the test mode 19.

(2) Subarray under test designating circuit 6 may be provided within address generator 3. Subarray under test designating circuit 6 may change the address after modulation 5a to provide Y address 6a and X address 6b which may designate an address of a subarray under test according to a test mode 19. In this way, a subarray (portion of an array) may be selected to implement the test.

Because only the selected subarray may be tested when running tests to access and read-out all other addresses after writing data in an optional address, the time required for testing may be greatly shortened.

(3) The address (row address 18 and column address 17) and test performed (test mode 19) may be provided external to BIST circuit 100 while executing a BIST.

Therefore, when a fault is detected on the RAM under test, rather than just indicating a fault has occurred, the fault location and defect mode in the RAM may be determined from the address and test performed.

Next a more specific embodiment is described.

In the following example, the RAM under test may be a DRAM (dynamic random access memory) or the like. A BIST circuit may implement a disturb-hold test rather than a checkerboard and/or marching test as in the conventional approach.

Before explaining the operation of the embodiment, a DRAM disturb-hold test is described.

Basic DRAM operations may include a write and a read operation. When an address is not being written to or read from, a data hold operation may occur.

A disturb-hold test may be executed by writing data into an address. While holding the data in the memory cell corresponding to the address, other memory cells may be accessed with read and/or write operations (reading or writing other addresses). The memory cell in which data is being held may be disturbed by the other memory cells. For example, disturb may occur through a cell-to-cell disturbance or due to sharing a word line or a bit line. As an example, a state where data is being held in a storage cell while writing/reading inverted data to/from other cells may provide a worst-case disturb-hold test. The data being held may then be read after a predetermined time to test the DRAM data holding properties.

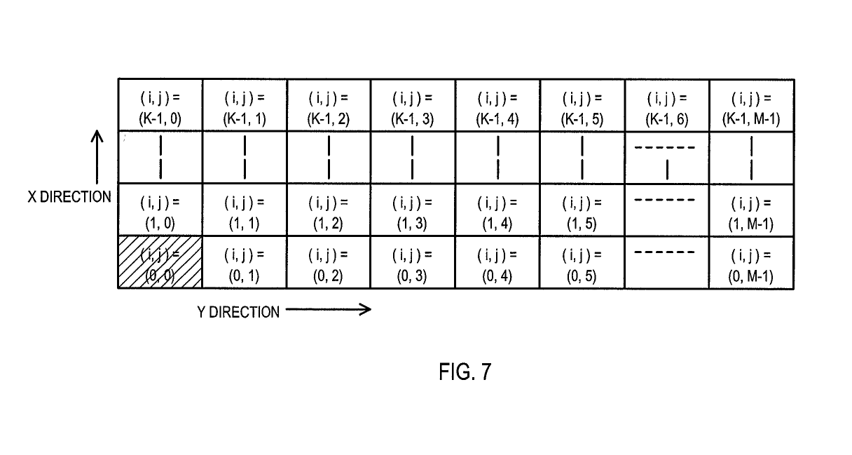

Referring now to FIG. 6, a diagram illustrating a disturb-hold test pattern is set forth.

The vertical axis shows an address of the DRAM under test and the horizontal axis shows the pattern progression direction. In this example, the number of addresses N is set to 8 for simplification. In the diagram of FIG. 6, the respective addresses on the DRAM are defined as 0 through N−1.

In the first step of the disturb-hold pattern, all cells (0 to N−1) may be written with write data.

Next, an odd disturb step may be executed. In the odd disturb step, only the even memory cells may be accessed and inverted data (compared to data in odd memory cells) may be written into the even memory cells. Inverted data may cause a disturb condition for data stored in the odd memory cells. A * may designate that these addresses may be skipped over in a step. The odd disturb step may be performed over a predetermined time period sufficient to check the DRAM data hold time.

Next an odd data check step may be executed. In the odd data check step, the odd memory cells may be accessed and data may be read out. The read out data may be checked to ensure that it matches the data that was originally written.

Next, in a similar way as in the odd disturb step, an even disturb step may be executed. In the even disturb step, only the odd memory cells may be accessed and inverted data (compared to data in even memory cells) may be written into the odd memory cells. This inverted data may cause a disturb condition for data stored in the even memory cells. The even disturb step may be performed over a predetermined time period sufficient to check the DRAM data hold time.

Next an even data check step may be executed. In the even data check step, the even memory cells may be accessed and data may be read out. The read out data may be checked to ensure that it matches the data that was originally written.

As integration increases and/or DRAM density increases, the memory cell array of the DRAM or DRAM macro may be divided into multiple subarrays. The subarrays may be arranged in a matrix in the X direction and Y direction.

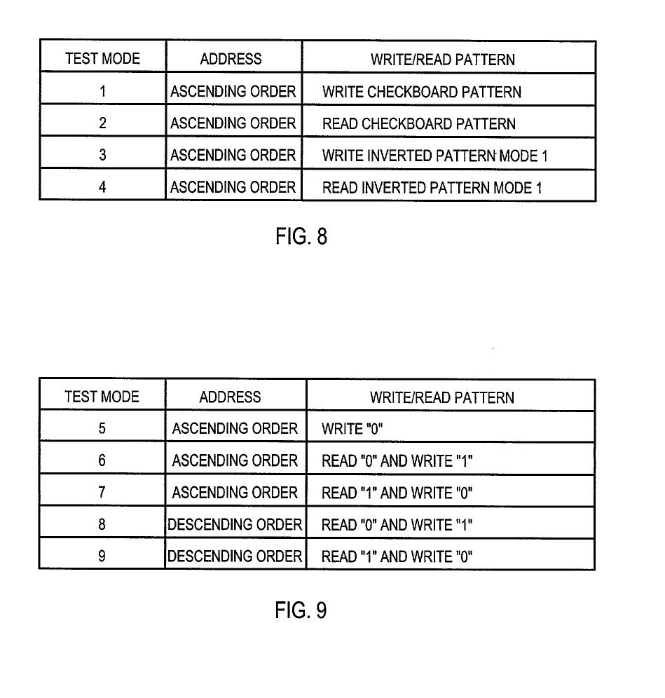

Referring now to FIG. 7, a plan diagram illustrating subarrays arranged in a matrix is set forth. In FIG. 7, the subarrays may be formed in a K×M matrix. Each subarray may be illustrated by (i,j) where i =0 to K−1 and j=0 to M−1. Subarray (0,0) may be shaded in this example.

By dividing a memory cell array into multiple subarrays, each memory cell may share a bit line (column) only with memory cells in the same column of the same subarray. Thus, during a disturb-hold test, only memory cells within a subarray may be access to perform the disturb step. In this way, a disturb-hold test may be performed having a shortened test time.

In the y direction, subarrays along the same row may have the same i value and may provide data values in the same word.

In BIST circuit 100, if using a construction of subarrays as set forth in FIG. 7 as an example and performing tests in word units, then the disturb-hold test may be performed K times in a similar manner, where i=0, 1, 2, . . ., K−1.

In the present embodiment, BIST circuit 100 may be used to perform the disturb-hold test, as well as other test modes. These other test modes performed by BIST circuit 100 will now be described.

Well known tests for a basic DRAM are (1) checkerboard test, (2) marching test, and

(3) disturb-hold test. These tests may be implemented as test modes in BIST circuit 100.

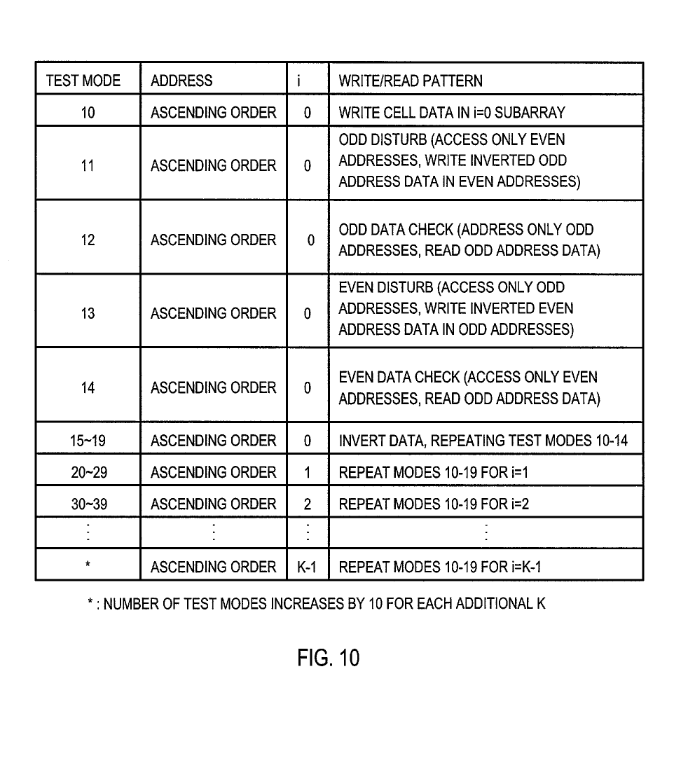

As example of a test mode performing a checkerboard test is shown in FIG. 8.

Referring now to FIG. 8, in a first step (test mode 1), data may be written in a checkerboard-like pattern in a memory cell array while incrementing the address. In a second step (test mode 2), data may be read out of the addresses and verified in a similar order in which written.

In a third step (test mode 3), an inverted pattern (compared to test mode 1) may be written in a checkerboard-like pattern in a memory cell array while incrementing the address. In a fourth step (test mode 4), data may be read out of the addresses and verified in a similar order in which written.

By implementing test modes 1 through 4, a memory cell may store a data value while adjacent memory cells may have an inverted data value for both a data zero and a data one.

In high-density DRAMs, memory cell arrangement in a memory cell array may be complex. In some cases, not all adjacent memory cells to a memory cell storing data may be written with opposite data and multiple test modes may be used for writing inverted data into all adjacent memory cells. Test modes (1 to 4) in FIG. 8 may include the multiple test modes.

Data hold properties may be tested by, for example, stopping a clock for a predetermined time after writing the checkerboard test. In contrast to the disturb-hold test, the testing of data hold properties when the DRAM is idle or in a standby state may be referred to as a static-hold or a pause test.

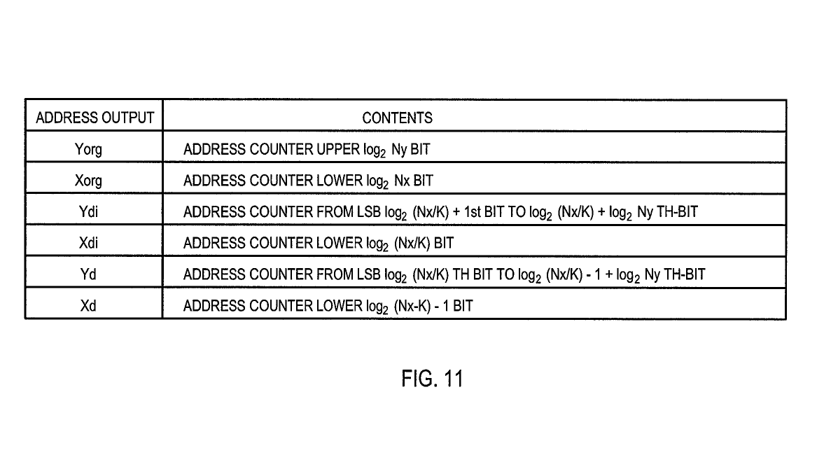

An example of a test mode performing a marching test is shown in FIG. 9.

Referring now to FIG. 9, in a first step (test mode 5), writing of “0” may be performed for addresses 0 through N in ascending order, for example. In a next step (test mode 6), for each memory cell (0 through N) the “0” may be read out and a “1” may be written in. The step of test mode 6 may be performed in ascending order. Then, in a next step (test mode 7), for each memory cell (0 through N), the “1” may be read out and a “0” may be written in. Likewise, the step of test mode 7 may be performed in ascending order.

Steps, similar to test modes 6 and 7, may then be performed in descending order as test modes 8 and 9.

The marching test shown in FIG. 9 may achieve a pattern length of 9N. In other words there may be nine operations (read or write) performed on each of the N memory cells. As such, the test may be referred to as a 9N marching test.

BIST circuit 100 may also include a disturb-hold test other than a static-hold or pause test.

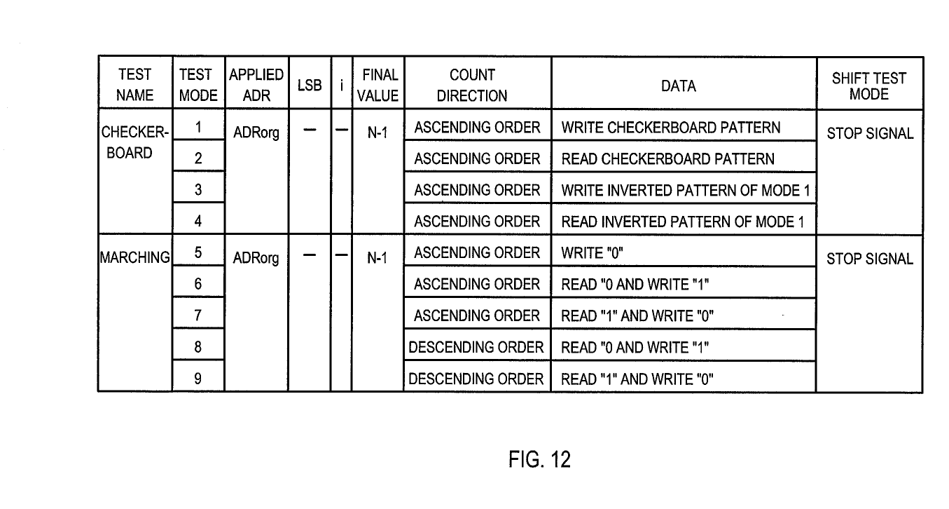

An example of a test mode performing a disturb-hold test is shown in FIG. 10.

Referring now to FIG. 10, in a first step (test mode 10), data may be written into memory cells of i=0 subarrays.

Next, in an odd disturb step (test mode 11), only the memory cells having even addresses in i=0 subarrays may be accessed and may have inverted data (with respect to memory cells having odd address) written into. This operation may be performed over a predetermined time period sufficient to check the DRAM data hold time.

Then, in an odd data check step (test mode 12), only the memory cells having even addresses in i=0 subarrays may be accessed and may have data read out and a check (odd data check) may be performed to verify data integrity.

Next, in a similar way as in the odd disturb step, an even disturb step (test mode 13) may be executed for the i= subarrays. In the even disturb step, only the odd memory cells of the i=0 subarrays may be accessed and inverted data (compared to data in even memory cells) may be written into the odd memory cells. This inverted data may cause a disturb condition for data stored in the even memory cells. The even disturb step may be performed over a predetermined time period sufficient to check the DRAM data hold time.

Next an even data check step (test mode 14) for the i=0 subarrays may be executed. In the even data check step, the even memory cells may be accessed and data may be read out. The read out data may be checked to ensure that it matches the data that was originally written.

Tests in which data may be inverted with respect to test modes 10 to 14 may be performed in test modes 15 to 19.

Essentially the same test may be performed on respective subarrays (i=1, 2, 3, . . .K−1) in test modes 20-29, 30-39, . . . , * as illustrated in FIG. 10.

BIST circuit 100 may implement test mode numbers as illustrated in FIGS. 8, 9, and 10. In this way, basic DRAM functions may be tested.

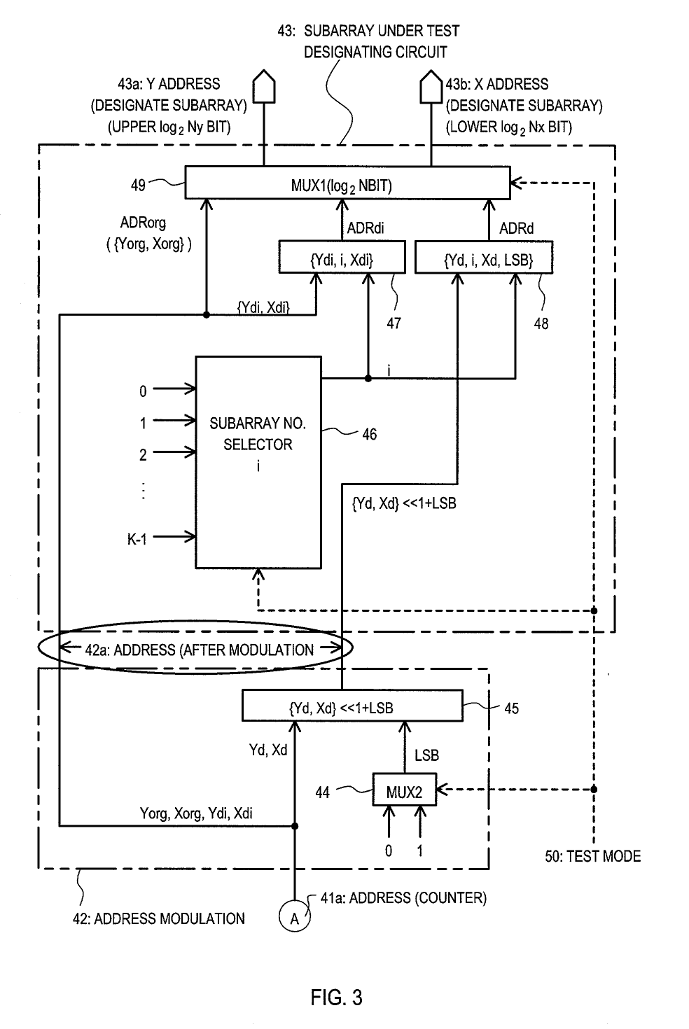

The structure of BIST circuit 100 is shown in FIGS. 3, 4, and 5.

FIG. 3 is a block schematic diagram of an address modulator circuit and subarray under test designating circuit of a BIST circuit according to an embodiment. FIG. 3 illustrates an address modulator circuit 42 and a subarray under test designating circuit 43. Address modulator circuit 42 may be used as address modulator circuit 5 in BIST circuit 100 of FIG. 1. Subarray under test designating circuit 43 may be used as subarray under test designating circuit 6 in BIST circuit 100 of FIG. 1.

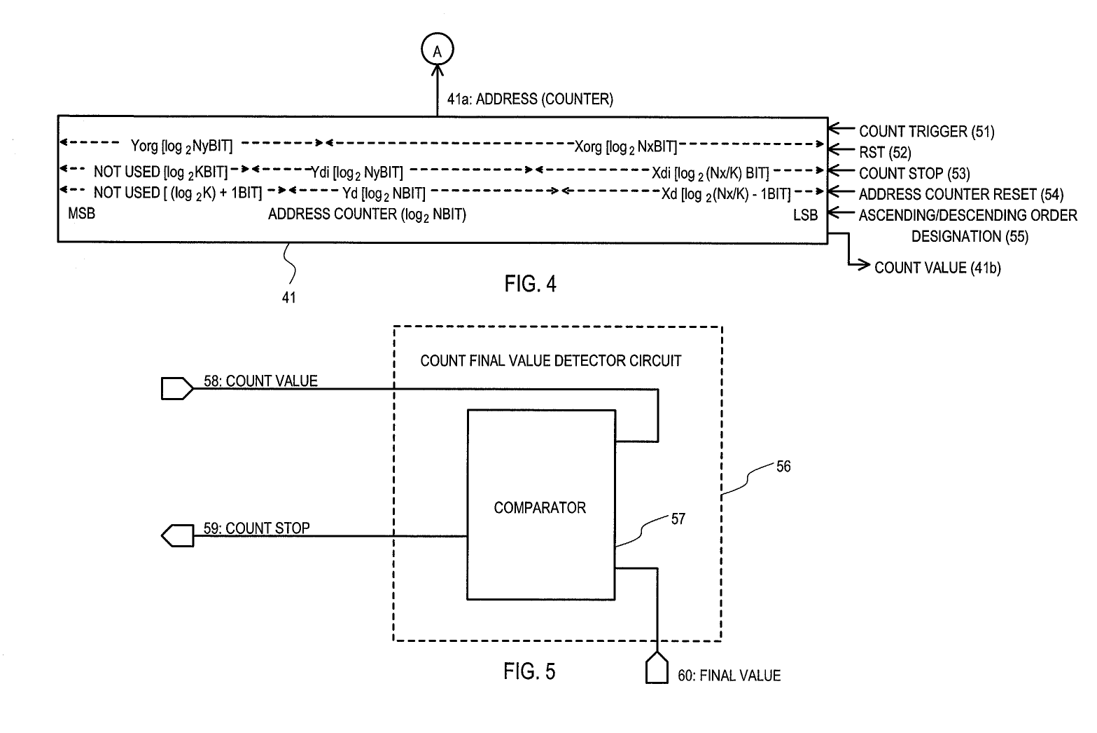

FIG. 4 is a block schematic diagram of an address counter of a BIST circuit according to an embodiment. FIG. 4 illustrates an address counter 41. Address counter 41 may be used as address counter 4 in BIST circuit 100 of FIG. 1.

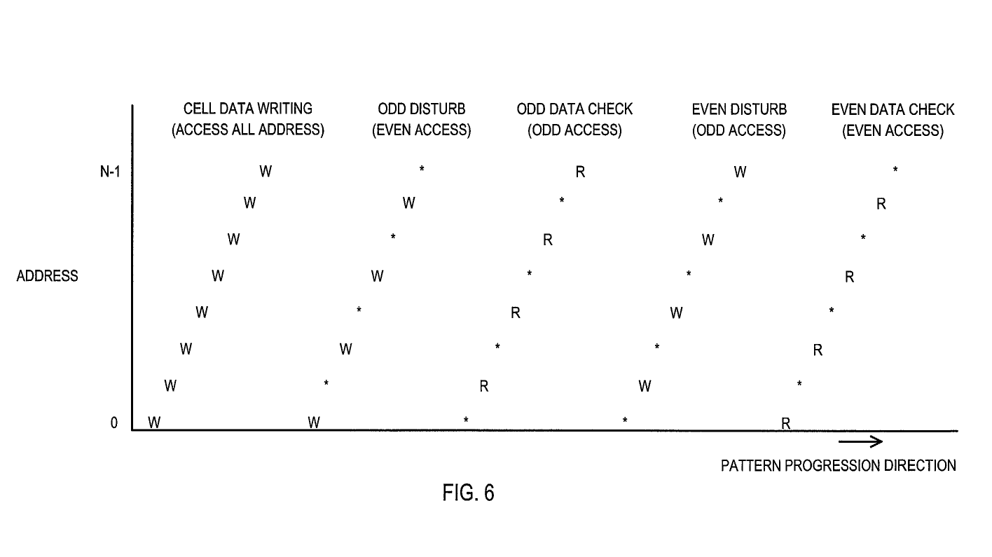

FIG. 5 is a block schematic diagram of a count final value detector of a BIST circuit according to an embodiment. FIG. 5 illustrates count final value detector 56. Count final value detector 56 may be used as count final value detector 8 in BIST circuit 100 of FIG. 1.

Referring now to FIG. 1, address generator 3 may generate row address 18 and column address 19 which may be used in an implementation of a DRAM test.

Address count 4a may be output from address counter 4 in address generator 3. A block schematic diagram of address counter 4 of FIG. 1 is illustrated as address counter 41 in FIG. 4.

Referring now to FIG. 4, address counter 41 may hold all the X address bits, for example if there are Nx X address values, there may be log₂Nx X address bits. Address counter may also hold all the Y address bits, for example, if there are Ny Y address values, there may be log₂Ny Y address bits. The X address bits may start at the LSB (least significant bit) side with the least significant X address bit. The Y address bits may be on the MSB (most significant bit) side with the most significant Y address bit being farthest left (MSB).

After a reset RST is terminated, (and after DRAM initialization is finished, depending on the type of DRAM), address counter 41 may increment from 0 each time a count trigger 51 is received. Address counter 41 may continue counting each time a count trigger 51 is received until an address counter reset signal 54 is received.

A count value 41b may return to 0 when count stop signal 53 is received. When this occurs, address counter 41 may begin counting again from 0.

Address counter 41 may stop counting regardless of the count stop signal 53 when address counter reset signal 54 is received. When this occurs, count value 41b may be reset and counting may begin again from 0.

Address counter 41 may continuously output a count value 41b. In this way, a count value 41b may be latched until a subsequent increment, stop, or reset command.

Address counter 41 may count as described above regardless as to the value of ascending/descending order designation signal 55. If ascending/descending order designating signal 55 is at a logic level indicating ascending order, the count value may be output as address count 41a. However, if ascending/descending order designating signal 55 is at a logic level indicating descending order, an inverted count value may be output as address count 41a.

Referring once again to FIG. 1, count final value detector 8 may receive count value 4b and final value 1a and may provide a count stop 8a. A block schematic diagram of count final value detector 8 of FIG. 1 is illustrated as count final value detector 56 in FIG. 5.

Referring now to FIG. 5, count final detector 56 may include a comparator 57. Comparator 57 may receive a count value 58 from address counter (for example address counter 41 of FIG. 4) and a final value 60. Comparator 57 may compare count value 58 and final value 60 and may output a count stop signal 59 when count value 58 matches final value 60.

Referring once again to FIG. 1, an address modulator circuit 5 may receive an address count 4a from address counter 4. Address modulator circuit 5 may also receive a test mode signal 19. Address modulator circuit 5 may provide an address after modulation 5a. A subarray under test designating circuit 6 may receive the address after modulation 5a and may output a Y address 6a and a X address 6b. A block schematic diagram of address modulator circuit 5 and subarray under test designating circuit 6 of FIG. 1 is illustrated as address modulator circuit 42 and subarray under test designating circuit 43 in FIG. 3.

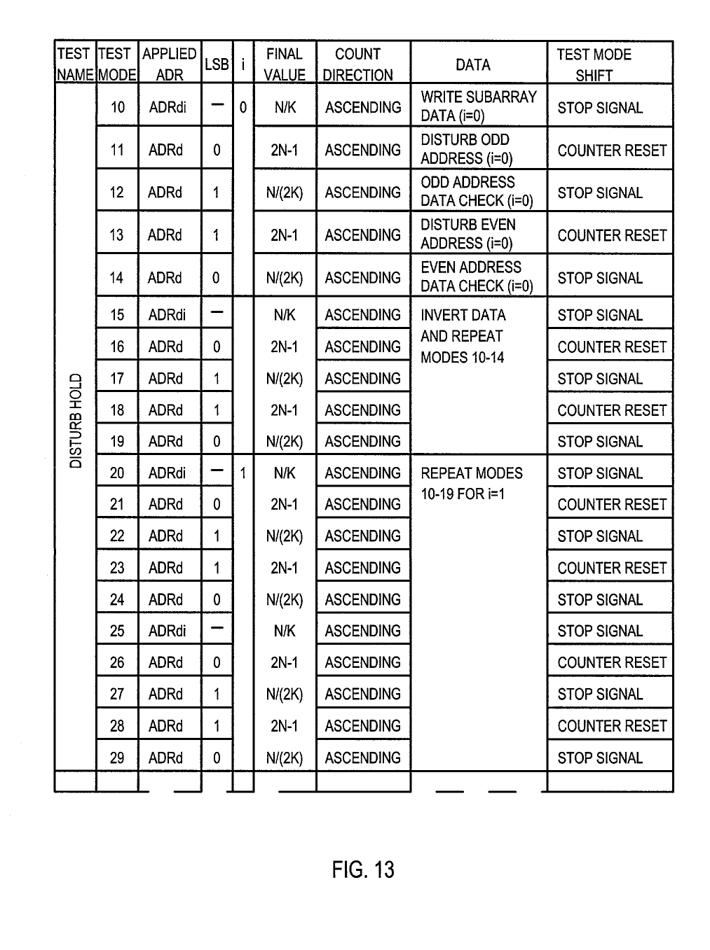

Referring now to FIG. 3, address modulator circuit 42 may receive an address count 41a (from address counter 41 of FIG. 4) and a test mode 50. In this embodiment, a modulation control signal 1e (FIG. 1) may not be used. Address count 41a may be capable of being categorized into the six types of signals as illustrated in the table of FIG. 11. Address count 41a may be categorized into Yorg, Xorg, Ydi, Xdi, Yd, and Xd.

Among values of address count 41a received by address modulator circuit 42, Yorg, Xorg, Ydi, and Xdi may be output unchanged from address modulator circuit 42 as a portion of address after modulation 42a.

{Yd, Xd} may be modulated in address modulator circuit 42. In other words, 1 or 0 may be substituted into the LSB of {Yd, Xd} shifted by 1-bit to the MSB side. A multiplexer (MUX2) 44 may determine whether the LSB is set to 1 or 0 in accordance with test mode 50. Circuit 45 may receive {Yd, Xd} and a LSB (“1” or “0”), and may provide {Yd, Xd}<<1+LSB. {Yd, Xd}<<1+LSB may symbolize shifting {Yd, Xd} by 1-bit to the MSB side and adding LSB.

In this way, an address after modulation 42a may be provided.

Subarray under test designating circuit 43 may receive address after modulation 42a and test mode signal 50.

Among the bits of address after modulation 42a, {Yorg, Xorg} may be received unchanged as ADRorg by a multiplexer (MUX1) 49. {Ydi, Xdi} may be received along with a subarray number i (output from a subarray number selection circuit 46) by a circuit {Ydi, i, Xdi} 47. Circuit {Ydi, i, Xdi} 47 may output ADRdi by inserting subarray number i in a digit between Ydi and Xdi. {Yd, Xd}<<1+LSB may be received along with a subarray number i (output from a subarray number selection circuit 46) by a circuit {Yd, i, Xd, LSB} 48. Circuit {Yd, i, Xd, LSB} 48 may output ADRd by inserting subarray number i in a digit between Ydi and Xdi. ADRd may be formed essentially as bits {Yd, i, Xd, LSB}.

Multiplexer (MUX1) 49 may receive ADRorg, ADRdi, and ADRd as inputs. MUX1 49 may select one of ADRorg, ADRdi, and ADRd to provide Y address 43a and X address 43b. Subarray number selection circuit 46 may select subarray No. i from among 0 through K−1 in accordance with a test mode 50.

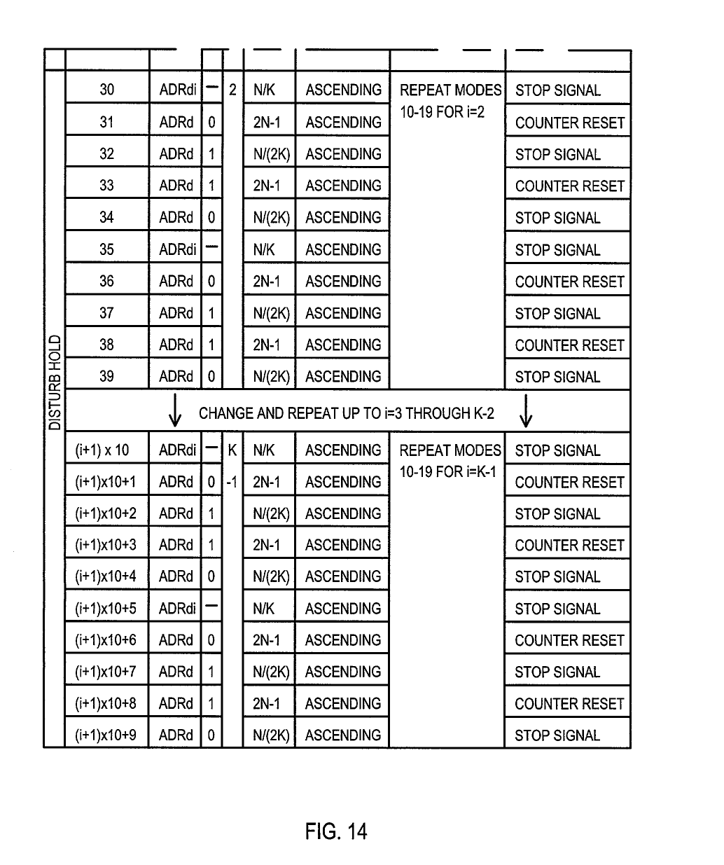

Now, test mode parameters of the present embodiment will be described with reference to FIGS. 12 through 14.

FIG. 12 is a table illustrating test modes for implementing a checkerboard test and a marching test according to an embodiment.

The table of FIG. 12 includes an input address (applied ADR) selected by MUX1 49 (FIG. 3), an LSB selected by MUX2 44 (FIG. 3), a final value (provided by test mode controller 1 (FIG. 1) as final value 1a), a count direction (provided by test mode controller 1 (FIG. 1) as ascending/descending order designation 1b), data (provided by test mode controller 1 (FIG. 1) as data 1c), and a shift test mode (indicating signal used to generate test mode switching signal 2a (FIG. 1)).

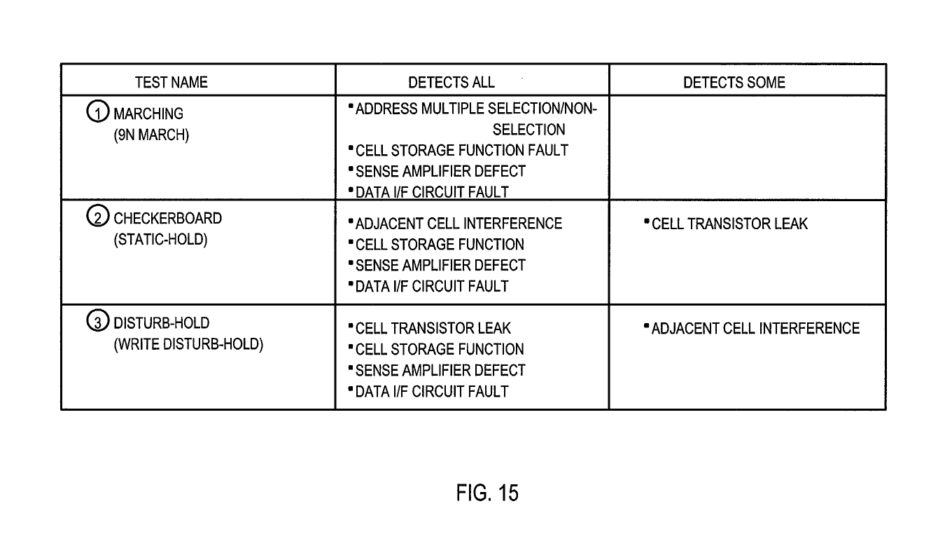

FIG. 13 and FIG. 14 are tables illustrating test modes for implementing a checkerboard test and a marching test according to an embodiment.

The table of FIGS. 13 and 14, also includes an input address (applied ADR) selected by MUX1 49 (FIG. 3), an LSB selected by MUX2 44 (FIG. 3), a final value (provided by test mode controller 1 (FIG. 1) as final value 1a), a count direction (provided by test mode controller 1 (FIG. 1) as ascending/descending order designation 1b), data (provided by test mode controller 1 (FIG. 1) as data 1c), and a shift test mode (indicating signal used to generate test mode switching signal 2a (FIG. 1)).

It should be noted that applied ADR may be Y address 43a and X address 43b.

In the tables of FIGS. 12-14, shift test mode may include a stop signal or a counter reset. A stop signal may be a count stop 8a generated by count final value detection circuit 8 in BIST circuit 100 of FIG. 1. A counter reset may be an address counter reset signal 11 as illustrated in BIST circuit 100 of FIG. 1.

In the table of FIG. 12, it can be seen that checkerboard and marching tests may use ADDorg as the applied ADR, which may bypass address modulator circuit 42 (FIG. 3). Thus, address counter 41 (FIG. 4) may provide the address up to an address maximum value (N−1).

Because address modulator circuit 42 (FIG. 3) may be bypassed, LSB may be a don't care.

This shows that a checkerboard test and a marching test may be implemented without using either address modulator circuit 42 or subarray under test designating circuit 43. In other words, these tests may be implemented with a conventional BIST circuit.

A description of sequencing of a disturb-hold test according to the embodiment will be discussed with reference to FIGS. 13 and 14 in conjunction with FIGS. 1 to 4. The sequencing will use, as an example, a disturb-hold test beginning at subarray (i=0).

In test mode 10, subarray data may be written. In this case, an input address (applied ADR) may be ADRdi, subarray number i may be set as 0. In this way, a subarray may be selected and data 0 may be written. A counter final value 60 (FIG. 5) may be N/K. In this way, when data is written to one subarray, counter value may become N/K and comparator 57 (FIG. 5) may generate a count stop signal 59 (FIG. 5). Thus, a test mode (test mode 10) may be terminated and a next test mode (test mode 11) may be initiated.

In test mode 11, a disturb odd address (i=0) may be executed. In this case, an input address (applied ADR) may be ADRd, LSB may be set as a 0 by MUX2 44 (FIG. 3), and subarray number i may be set to 0. Because LSB is set to 0 and subarray number i is set to 0, subarray under test designating circuit 43 may write data (opposite data with respect to data in odd addresses) only in even addresses of subarray 0.

Counter final value 60 (FIG. 5) may be 2N−1. Thus, an N-bit counter, such as counter 41 (FIG. 4), may continue counting endlessly. However, in this case, a counter reset signal 54 (FIG. 4) may be provided from outside BIST circuit 100 to terminate the test mode (test mode 11). When the test mode (test mode 11) is terminated, a next test mode (test mode 12) may be initiated.

In test mode 12, an odd address data check (i=0) may be executed. In this case, an input address (address ADR) may be ADRd and LSB may be set as a 1 by MUX2 44 (FIG. 3). Thus, subarray under test designating circuit 43 may only generate odd addresses. A count final value may be set to N/(2K). In this way, a data check of one subarray may be performed in the test mode (test mode 12).

In test mode 13, a disturb even address (i=0) may be executed. In this case, an input address (applied ADR) may be ADRd and LSB may be set to 1 by MUX2 44 (FIG. 3). Thus, subarray under test designating circuit 43 may only generate odd addresses. In this way, data (opposite data with respect to data in even addresses) may be written only in odd addresses of subarray 0. Counter final value 60 (FIG. 5) may be 2N−1. Thus, an N-bit counter, such as counter 41 (FIG. 4), may continue counting endlessly. However, in this case, a counter reset signal 54 (FIG. 4) may be provided from outside BIST circuit 100 to terminate the test mode (test mode 13). When the test mode (test mode 13) is terminated, a next test mode (test mode 14) may be initiated.

In test mode 14, a even address data check (i=0) may be executed. In this case, an input address (address ADR) may be ADRd and LSB may be set as a 0 by MUX2 44 (FIG. 3). Thus, subarray under test designating circuit 43 may only generate even addresses. A count final value may be set to N/(2K). In this way, an even address data check of one subarray may be performed in the test mode (test mode 14).

Test modes 15 to 19 may essentially be the same as test modes 10 to 15, except inverted data may be written and read with respect to test modes 10 to 15. In this way disturb-hold tests may be tested for both data values.

It should be noted that, although not mentioned above, disturb test modes, such as test modes 11 and 13, may be executed over a predetermined time in order to check data hold properties as desired.

Input address (applied ADR) may be ADRdi when all bits are to be written to in an array i. However, when only even or odd bits are to be written to or read from, input address (applied ADR) may be selected as ADRd by MUX1 49 (FIG. 3). When odd addresses are written to or read from, LSB may be set to 1 by MUX2 44 (FIG. 3). When even addresses are written to or read from, LSB may be set to 0 by MUX2 44.

The subarray to be tested may be changed by changing the value of i.

As described above, the present embodiment may perform operations as illustrated in FIGS. 13 and 14 to implement disturb-hold tests that may require complex address patterns. Such tests may be impossible to achieve with conventional BIST circuits.

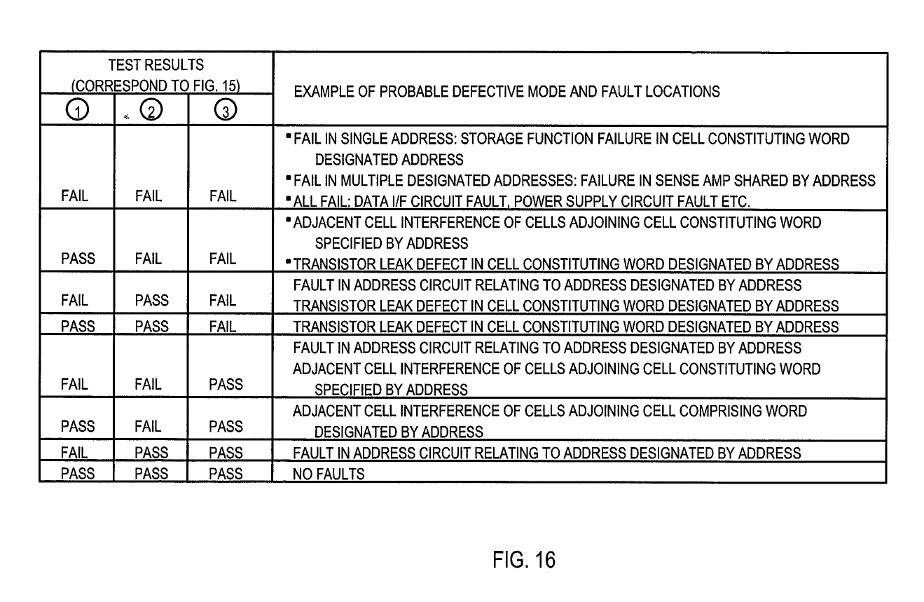

FIG. 15 is a table showing the relation between tests implemented in the present embodiment and defect modes in a DRAM that can be detected.

In FIG. 15, “Detects All” indicates that all defects/faults listed in the box may be detected if they occur on a DRAM under test. “Detects Some” indicates that faults occurring on the DRAM under test may be detected, but detection capability may be poor.

For example, a disturb-hold test according to the embodiment may detect all defects caused by cell transistor leakage. However, in the checkerboard test, detection capability of defects caused by cell transistor leakage may be poor.

As illustrated in FIG. 15, detectable defect modes may be different depending on the test executed. Thus, depending on the pass/fail status of the collective tests, a probable defect mode may be determined.

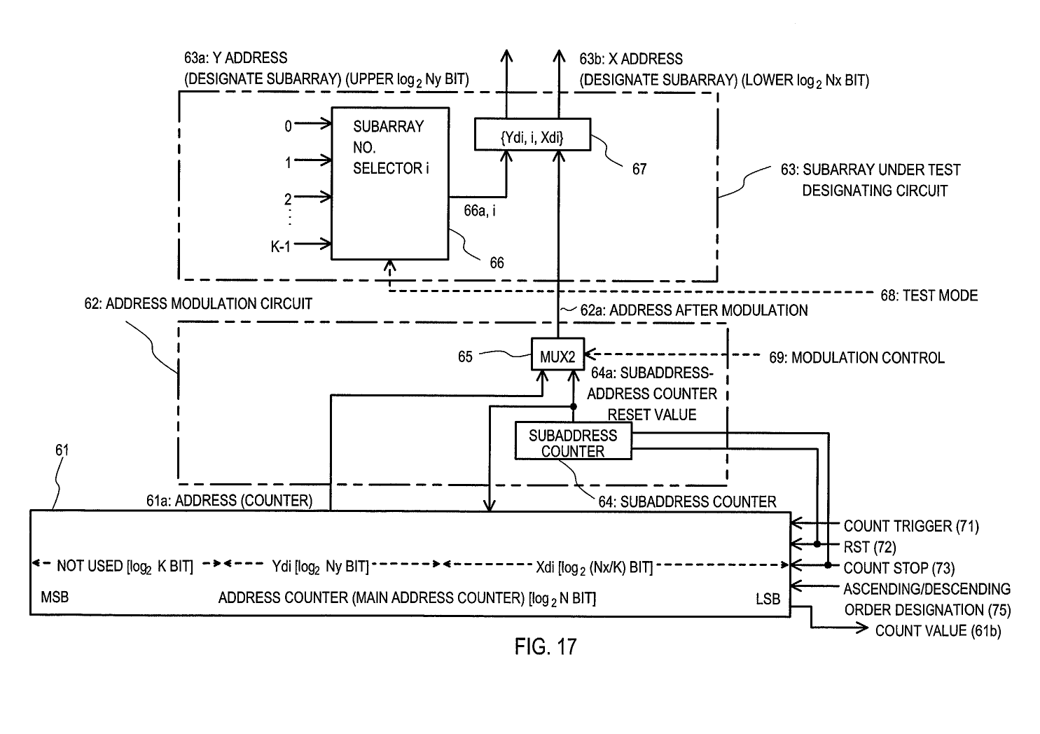

FIG. 16 is a table illustrating a probable defect mode based on pass/fail results of each of the collective tests (marching, checkerboard, and disturb-hold). Thus, the defect mode may be estimated by monitoring the pass/fail of each bit for each of the collective tests and the fault location may be estimated by monitoring values of row address 18 (FIG. 1) and column address 17 (FIG. 1).

An embodiment for a BIST circuit providing a test for a fast galloping pattern will now be described.

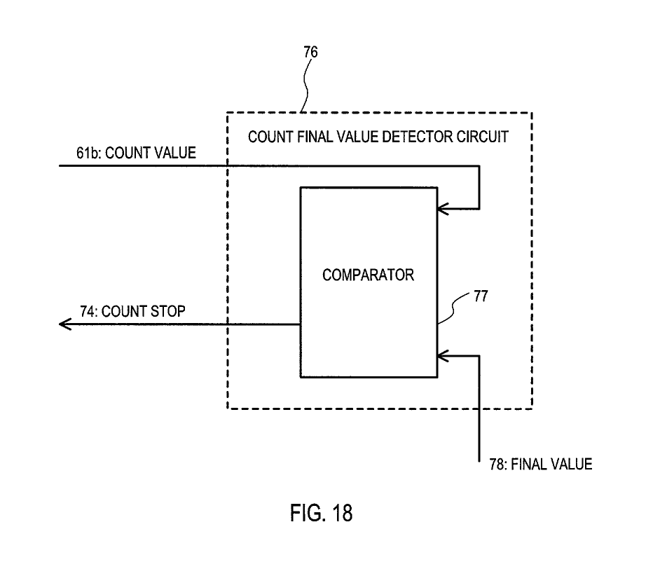

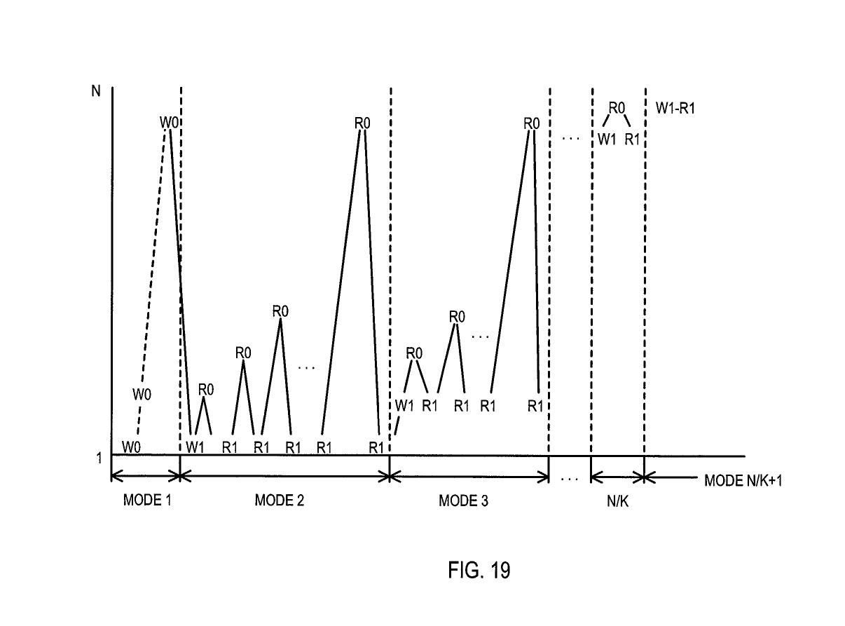

FIG. 17 is a block schematic diagram of an address counter 61, an address modulation circuit 62, and a subarray under test designating circuit 63 according to an embodiment. FIG. 18 is a block schematic diagram of a count final value detector circuit 56 according to an embodiment.

The embodiment components illustrated in FIGS. 17 and 18 may be essentially the same as the embodiment components of a BIST circuit 100 in FIG. 1 except for the address counter 61.

Referring now to FIG. 17, after terminating a reset (shown as RST 72), address counter 61 may start counting up in synchronism with a count trigger 71.

The output (address (counter) 61a) from address counter 61 may be received by multiplexer MUX2 65 in address modulation circuit 62.

After terminating the RST 72, a subaddress counter 64 in address modulation circuit 62 may begin counting up upon receiving count stop signal 73.

Subaddress counter 64 may output a subaddress 64a, which may be received by MUX2 65 and address counter 61.

MUX2 65 may receive a modulation control signal 69 and may select subaddress 64a or address (counter) 61a to output as an address after modulation 62a.

Subarray under test designating circuit 63 may receive address after modulation 62a as an input to a circuit {Ydi, i, Xdi} 67. Circuit {Ydi, i, Xdi} 67 may also receive a subarray number i at another input and may provide Y address 63a and X address 63b by merging subarray number i with address after modulation 62a.

Referring now to FIG. 18, count final value detector circuit 76 may receive a count value 61b from address counter 61 and a final value 78. Final value 78 may be provided from a test mode controller, such as test mode controller 1 of BIST circuit 100 (FIG. 1). Count final value detector circuit 76 may compare count value 61b and final value 78 with a comparator 77 and may output a count stop signal 74 when a match is detected.

The operation of the embodiment illustrated in FIGS. 17 and 18 will now be described.

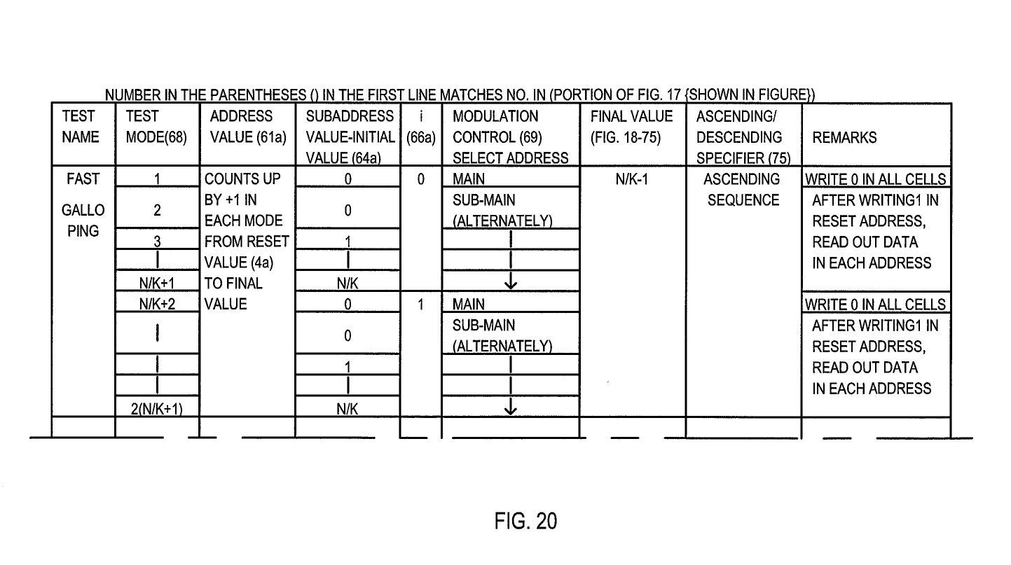

First, a simple explanation of a fast galloping pattern generated by a BIST circuit including circuits as illustrated in FIGS. 17 and 18 will be given with reference to FIG. 19.

FIG. 19 is a chart illustrating a fast galloping pattern according to an embodiment.

In a first mode (mode 1), a data value “0” may be written to all memory cells.

In a second mode (mode 2), in an address of a first cell to be tested (in this example, address 1), a data value “1” may be written. Then read operations may be executed in which a next cell (address greater than the first cell) followed by the first cell are addressed. These read operations may continue until all cells are read. Data values may be verified with an expected data value.

In a third mode (mode 3), a data value “1” in an address of a second cell to be tested (in this example, address 2), a data value “1” may be written. Then read operations may be executed in which a next cell (address greater than the second cell) followed by the second cell are addressed. These read operations may continue until all cells having an address greater than the second cell are read. Data values may be verified with an expected data value.

This pattern may continue until an N/K+1 mode (mode N/K+1), in which a one may be written into an N/K cell. Then a read operation may be executed on the N/K cell. A data value may be verified with the expected data value.

The above pattern may be repeated for all subarrays.

The process may then be repeated with inverted data (initially writing a data value “1” to all memory cells).

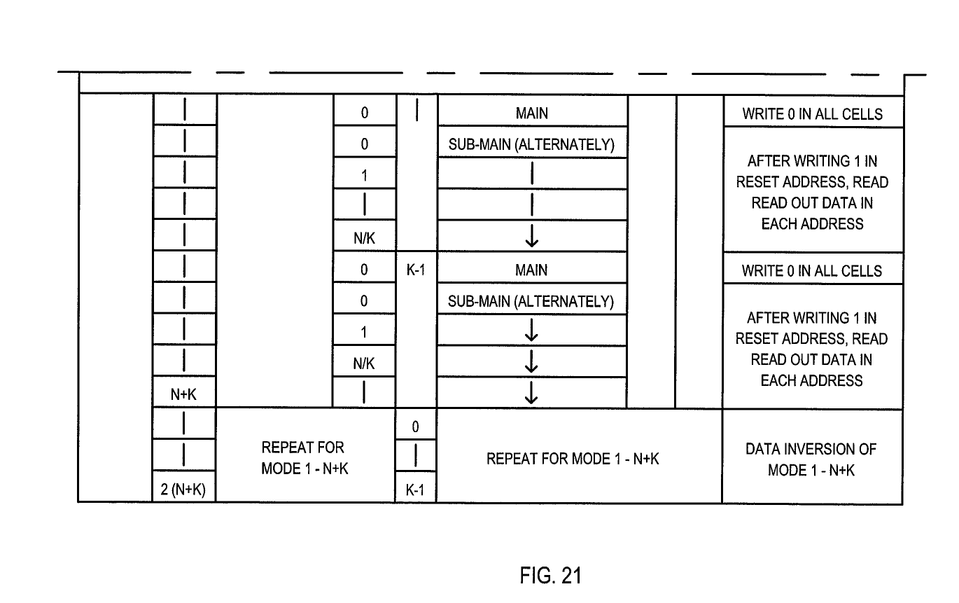

FIGS. 20 and 21 are tables illustrating sample states/values of signals with a BIST circuit including circuits of FIGS. 17 and 18 according to an embodiment.

Referring now to FIGS. 20 and 21 in conjunction with FIGS. 17 and 18, the fast galloping test according to an embodiment will be further described for an operation at a time when subarray i=0 (test modes 1 through N/K+1).

In a test mode (test mode 1) address counter 61 (FIG. 17) may count up from a reset value of 0 as subaddress 64a value to a final value 75 of N/K−1 in increments of +1 while writing a value of “0” in all cells.

In a next test mode (test mode 2), a data value of “1” may be written in address “0” (designated by the reset value set as subaddress 64a in subaddress counter 64). The value set as subaddress 64a may also be loaded into address counter 61.

MUX2 65 may select an address (counter) 64a, which may be incremented from a value set from subaddress 64a. In this way, a read may be executed on a next address (address 1).

Hereafter, MUX2 65 may alternate between selecting subaddress 64a and address (counter) 61a. Address (counter) 61a may increment in accordance with a count trigger 71.

Address (counter) 61a may increment until a final value 78 may be reached by count value 61b and count final value detector circuit 71 may provide a count stop 73. In this way, a test mode (test mode 2) may be terminated and an operation as illustrated in FIG. 19 (Mode 2) may be completed. Subaddress 64a may then be incremented by subaddress counter 64.

This operation may repeat from the new value of subaddress 64a on through a final value of N/K−1 in subsequent test modes (test mode 3 through N/K+1).

Test modes 1 through N/K+1 may be repeated from i=0 to K−1 (test modes I through N+K). Data may then be inverted and the operation of test modes 1 through N+K may be repeated (test modes N+K+1 through 2(N+K).

As described above according to an embodiment, a BIST circuit may include circuits as illustrated in FIGS. 17 and 18 and may generate fast galloping patterns which may not be possible with a conventional BIST circuit.

A semiconductor integrated circuit having a BIST circuit according to the embodiments may perform tests other than a checkerboard test and marching test.

The term signal may be used to signify a group of bits of, for example, an address or data. As just one example, a test mode signal may be a group of test mode data bits.

It is understood that the embodiments described above are exemplary and the present invention should not be limited to those embodiments. Specific structures should not be limited to the described embodiments.

Thus, while the various particular embodiments set forth herein have been described in detail, the present invention could be subject to various changes, substitutions, and alterations without departing from the spirit and scope of the invention. Accordingly, the present invention is intended to be limited only as defined by the appended claims.

What is claimed is:

1. A semiconductor integrated circuit for testing a random access memory (RAM), comprising:
an address counter that changes an address of the RAM and provides an address count;
an address modulator circuit coupled to receive the address count and modulate the address count in accordance with a test mode to provide a modulation address; and
a RAM interface block coupled to provide a test command to the RAM on the basis of the modulated address and the test mode.

2. The semiconductor integrated circuit according to claim 1, wherein:
the address counter increments the address of the RAM.

3. The semiconductor integrated circuit according to claim 1, wherein:
the address counter decrements the address of the RAM.

4. The semiconductor integrated circuit according to claim 1, wherein:
a memory cell array of the RAM is divided into a plurality of subarrays;
the semiconductor integrated circuit further includes a designating circuit coupled to receive the modulation address and provide a designated subarray address; and
the RAM interface block provides the test command on the basis of the designated subarray address and the test mode.

5. The semiconductor integrated circuit according to claim 1, further including:
a count final value detector circuit wherein the count final value detector circuit resets the address counter and terminates the test in progress when the address count reaches a predetermined count final value.

6. The semiconductor integrated circuit according to claim 1, wherein:
the address counter is reset to terminate the test in progress in response to an address counter reset signal provided from outside the semiconductor integrated circuit.

7. The semiconductor integrated circuit according to claim 1, wherein:
a test mode indicator and an address received by the RAM are provided as semiconductor integrated circuit outputs.

8. A semiconductor integrated circuit including a memory and a built in self test (BIST) circuit for the memory, the BIST circuit comprising:
an address counter providing an address count;
an address modulator circuit coupled to receive at least a first portion of the address count and provide an address modulator output in accordance with a test mode and the at least a first portion of the address count; and
a memory interface block coupled to receive the address modulator output and provide a test command to the memory.

9. The semiconductor integrated circuit according to claim 8, wherein:
the memory is a dynamic random access memory (DRAM).

10. The semiconductor integrated circuit according to claim 9, wherein:
the BIST circuit provides a disturb-hold test.

11. The semiconductor integrated circuit according to claim 8, wherein the memory includes a plurality of subarrays, the BIST circuit further including:
a subarray under test designating circuit coupled to receive a test mode indicator and select a subarray to be tested.

12. The semiconductor integrated circuit according to claim 8, wherein:
the address modulator circuit includes a selector that designates the address modulator output to be even in response to a first test mode and designates the address modulator output to be odd in response to a second test mode.

13. The semiconductor integrated circuit according to claim 8, wherein:
the address counter is coupled to receive an increment/decrement signal having an increment logic level and a decrement logic level; and
the address counter provides the address count in an incrementing sequence when the increment/decrement signal has the increment logic level and provides the address count in a decrementing sequence when the increment/decrement signal has the decrement logic level.

14. The semiconductor integrated circuit according to claim 8, wherein:
the BIST circuit further includes a selector circuit coupled to provide at least a second portion of the address count to the memory interface block in a first test mode and the address modulator output to the memory interface block in a second test mode.

15. A semiconductor integrated circuit including a memory divided into a plurality of subarrays and a built in self test (BIST) circuit for the memory, the BIST circuit comprising:
an address generator providing a test address based on a counter output and a subarray address; and
a memory interface block coupled to receive the test address and a test mode and provide a test command to the memory.

16. The semiconductor integrated circuit according to claim 15, wherein:
the test command includes a memory test address and at least one memory control signal.

17. The semiconductor integrated circuit according to claim 15, wherein:
a test mode indicator and the test address are provided to circuits external to the BIST circuit.

18. The semiconductor integrated circuit according to claim 15, wherein:
the BIST circuit provides at least one test from the group consisting of a marching test, a checkerboard test, and a disturb-hold test.

19. The semiconductor integrated circuit according to claim 15, wherein:
the memory is a dynamic random access memory.

20. The semiconductor integrated circuit according to claim 15, wherein:
the address generator includes a final value detection circuit coupled to provide a count stop signal to a counter providing the counter output.
